(19) United States
(12) Patent Application Publication
(10) Pub. No.: US 2006/0249370 A1
(43) Pub. Date: Nov. 9, 2006

(54) Back-biased face target sputtering based liquid crystal display device

(76) Inventor: Makoto Nagashima, Tokyo (JP)

Correspondence Address: Bao Tran;Tran & Associates, 6768 Meadow Vista Court, San Jose, CA, 95135, US

(21) Appl. No.: 11/486,470

(22) Filed: Jul. 14, 2006

Related U.S. Application Data
(63) Continuation-in-part of application No. 10/662,862, filed on Sep. 15, 2003, now Pat. No. 6,962,648.
(63) Continuation-in-part of application No. 11/301,486, filed on Dec. 13, 2005.

(51) Int. Cl. C23C 14/32; C23C 14/00

(52) U.S. Cl. 204/192.1; 204/298.16

(57) ABSTRACT

Systems and methods are disclosed for forming memory arrays on a substrate in an air-tight chamber in which an inert gas is admittable and exhaustible; a pair of target plates placed at opposite ends of said air-tight chamber respectively so as to face each other and form a plasma region therebetween; a pair of magnets respectively disposed adjacent to said target plates such that magnet poles of different polarities face each other across said plasma region thereby to establish a magnetic field of said plasma region between said target plates; a substrate holder disposed adjacent to said plasma region, said substrate holder adapted to hold a substrate on which an alloyed thin film is to be deposited; and a back-bias power supply coupled to the substrate holder.

### BACKGROUND

This Application is a continuation in part (CIP) application of Ser. Nos. 10/662,862 and 11/301,486, the contents of which are incorporated by reference.

The present invention relates to systems and methods for fabricating semiconductor devices at low temperature.

Electronic systems have become a ubiquitous fixture in modern society. These electronic systems range from simple, hand-held calculators to more complex systems including computers, personal digital assistants (PDAs), embedded controllers and complex satellite imaging and communications systems. As noted in U.S. Pat. No. 6,862,211, many electronic systems include a microprocessor that performs one or more functions based on data provided to the microprocessor. This data is typically stored in a memory device of the electronic system such as a common dynamic random access memory (DRAM) device. A DRAM typically includes an array of memory cells that store data as binary values, e.g., 1's and 0's. In a conventional DRAM, the data is stored by controlling the charge on capacitors in each cell of the DRAM. Data in the array is “randomly accessible” since a processor can retrieve data from any location in memory by providing the appropriate address to the memory device. One problem with conventional DRAM is that the device is “volatile.” This means that when power is turned off to the system using the DRAM, the data in the memory device is lost.

In a parallel trend, various semiconductor fabrication steps need to be done at low temperature. For instance, when applying a ferroelectric thin film to a highly integrated device, conventional processes do not provide a ferroelectric thin film which sufficiently fulfills various conditions, such as denseness and evenness on the thin film surface required for fine processing and formation of film at a relatively low temperature.

U.S. Pat. No. 5,000,834 discloses a vacuum deposition technique known as face target sputtering to form thin films on magnetic recording heads at low temperature. The sputtering method is widely used for forming a thin film on a substrate made of PMMA because of intimacy between the substrate and the thin film formed therethrough. The amorphous thin film of rare earth—transition metal alloy formed through the sputtering method is applied to an erasable magneto-optical recording medium. The sputtering method is performed as follows: Positive ions of an inert gas such as Argon (Ar) first created by a glow discharge are accelerated toward a cathode or target, and then they impinge upon the target. As a result of ionic bombardment, neutral atoms and ions are removed from the target surface into a vacuum chamber due to the exchange of momentum therebetween. The liberated or sputtered atoms and ions are consequently deposited on a preselected substrate disposed in the vacuum chamber.

U.S. Pat. No. 6,156,172 discloses a plasma generating unit and a compact configuration of the combination of plasma space and substrate holders for a facing target type sputtering apparatus which includes: an arrangement for defining box-type plasma units supplied therein with sputtering gas mounted on outside wall-plates of a closed vacuum vessel; at least a pair of targets arranged to be spaced apart from and face one another within the box-type plasma unit, with each of the targets having a sputtering surface thereof; a framework for holding five planes of the targets or a pair of facing targets and three plate-like members providing the box-type plasma unit so as to define a predetermined space apart from the pair of facing targets and the plate-like members, which framework is capable of being removably mounted on the outside walls of the vacuum vessel with vacuum seals; a holder for the target having conduits for a coolant; an electric power source for the targets to cause sputtering from the surfaces of the targets; permanent magnets arranged around each of the pair of targets for generating at least a perpendicular magnetic field extending in a direction perpendicular to the sputtering surfaces of the facing targets; devices for containing the permanent magnets with target holders, removably mounted on the framework; and a substrate holder at a position adjacent the outlet space of the sputtering plasma unit in the vacuum vessel. The unified configuration composed of a cooling device for cooling both the backside plane of the targets and a container of magnets in connection with the framework improves the compactness of sputtering apparatus.

### SUMMARY

In one aspect, a facing targets sputtering device for semiconductor fabrication includes an air-tight chamber in which an inert gas is admittable and exhaustible; a pair of target plates placed at opposite ends of said air-tight chamber respectively so as to face each other and form a plasma region therebetween; a pair of magnets respectively disposed adjacent to said target plates such that magnet poles of different polarities face each other across said plasma region thereby to establish a magnetic field of said plasma region between said target plates; a substrate holder disposed adjacent to said plasma region, said substrate holder adapted to hold a substrate on which an alloyed thin film is to be deposited; and a back-bias power supply coupled to the substrate holder.

In another aspect, a method for sputtering a thin film onto a substrate includes providing at least one target and a substrate having a film-forming surface portion and a back portion; creating a magnetic field so that the film-forming surface portion is placed in the magnetic field with the magnetic field induced normal to the substrate surface portion; back-biasing the back portion of the substrate; and sputtering material onto the film-forming surface portion.

Advantages of the invention may include one or more of the following. The substrate temperature in forming a thin film is approximately that of room temperature, and the process requires a short time. Since the thin film is formed at a very low temperature during substantially the whole process, the process can be applied to a highly integrated device to deposit an additional layer with a plurality of elements without damaging other elements previously deposited using conventional deposition.

### BRIEF DESCRIPTION OF THE FIGURES

In order that the manner in which the above-recited and other advantages and features of the invention are obtained, a more particular description of the invention briefly described above will be rendered by reference to specific embodiments thereof, which are illustrated, in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 shows one embodiment of an apparatus for fabricating semiconductor.

FIG. 2 is an exemplary electron distribution chart.

FIG. 3 shows one embodiment of an FTS unit.

FIG. 4A shows one embodiment of a second apparatus for fabricating semiconductor.

FIG. 4B shows one embodiment of a second apparatus for fabricating semiconductor.

FIG. 5 shows an SEM image of a cross sectional view of an exemplary device fabricated with the system of FIG. 1.

FIG. 6 is an enlarged view of one portion of the SEM image of FIG. 5.

FIG. 7 shows an exemplary memory array made using the system of FIG. 1.

FIG. 8 shows an exemplary FPGA configuration memory made using the system of FIG. 1.

FIG. 9 shows an exemplary LCD made using the system of FIG. 1.

### DESCRIPTION

Referring now to the drawings in greater detail, there is illustrated therein structure diagrams for a semiconductor processing system and logic flow diagrams for processes a system will utilize to deposit a memory device at low temperature, as will be more readily understood from a study of the diagrams.

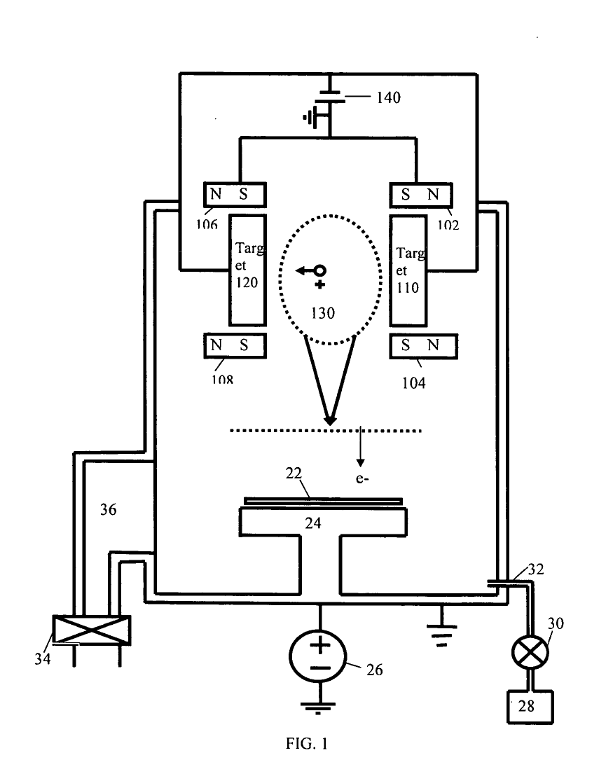

FIG. 1 shows one embodiment of an apparatus for fabricating semiconductor. An embodiment reactor 10 is schematically illustrated in FIG. 1. The reactor 10 includes a metal chamber 14 that is electrically grounded. A wafer or substrate 22 to be sputter coated is supported on a pedestal electrode 24 in opposition to the target 16. An electrical bias source 26 is connected to the pedestal electrode 24. Preferably, the bias source 26 is an RF bias source coupled to the pedestal electrode 24 through an isolation capacitor. Such bias source produces a negative DC self-bias VB on the pedestal electrode 24 on the order of tens of volts. A working gas such as argon is supplied from a gas source 28 through a mass flow controller 30 and thence through a gas inlet 32 into the chamber. A vacuum pump system 34 pumps the chamber through a pumping port 36.

An FTS unit is positioned to face the wafer 22 and has a plurality of magnets 102, 104, 106, and 108. A first target 110 is positioned between magnets 102 and 104, while a second target 120 is positioned between magnets 106 and 108. The first and second targets 110 and 120 define an electron confining region 130. A power supply 140 is connected to the magnets 102-108 and targets 110-120 so that positive charges are attracted to the second target 120. During operation, particles are sputtered onto a substrate 22 which, in one embodiment where the targets 110 and 120 are laterally positioned, is vertically positioned relative to the lateral targets 110 and 120. The substrate 22 is arranged to be perpendicular to the planes of the targets 110 and 120. A substrate holder 24 supports the substrate 22.

The targets 110 and 120 are positioned in the reactor 10 in such a manner that two rectangular shape cathode targets face each other so as to define the plasma confining region 130 therebetween. Magnetic fields are then generated to cover vertically the outside of the space between facing target planes by the arrangement of magnets installed in touch with the backside planes of facing targets 110 and 120. The facing targets 110 and 120 are used as a cathode, and the shield plates are used as an anode, and the cathode/anode are connected to output terminals of the direct current (DC) power supply 140. The vacuum vessel and the shield plates are also connected to the anode.

Under pressure, sputtering plasma is formed in the space 130 between the facing targets 110 and 120 while power from the power source is applied. Since magnetic fields are generated around the peripheral area extending in a direction perpendicular to the surfaces of facing targets 110 and 120, highly energized electrons sputtered from surfaces of the facing targets 110 and 120 are confined in the space between facing targets 110 and 120 to cause increased ionized gases by collision in the space 130. The ionization rate of the sputtering gases corresponds to the deposition rate of thin films on the substrate 22, then, high rate deposition is realized due to the confinement of electrons in the space 130 between the facing targets. The substrate 22 is arranged so as to be isolated from the plasma space between the facing targets 110 and 120.

Film deposition on the substrate 22 is processed at a low temperature range due to a very small number of impingement of plasma from the plasma space and small amount of thermal radiation from the target planes. A typical facing target type of sputtering method has superior properties of depositing ferromagnetic materials at high rate deposition and low substrate temperature in comparison with a magnetron sputtering method. When sufficient target voltage VT is applied, plasma is excited from the argon. The chamber enclosure is grounded. The RF power supply 26 to the chuck or pedestal 24 causes an effective DC ‘back-bias’ between the wafer and the chamber. This bias is negative, so it repels the low-velocity electrons.

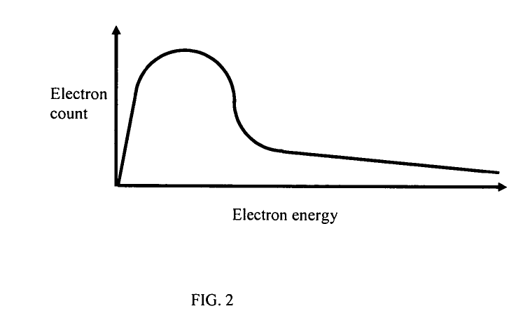

FIG. 2 illustrates an exemplary electron distribution for the apparatus of FIG. 1. The electron distribution follows a standard Maxwellian curve. Low energy electrons have two characteristics: they are numerous and they tend to have non-elastic collisions with the deposited atoms, resulting in amorphization during deposition. High-energy electrons come through the back-biased shield, but they effectively “bounce” off the atoms without significant energy transfer—these electrons do not affect the way bonds are formed. This is especially true because high energy electrons spend very little time in the vicinity of the atoms, while the low energy electrons spend more time next to the atoms and can interfere with bond formation.

The presence of the large positively biased shield affects the plasma, particularly those close to the pedestal electrode 24. As a result, the DC self-bias developed on the pedestal 24, particularly by an RF bias source, may be more positive than for the conventional large grounded shield, that is, less negative since the DC self-bias is negative in typical applications. It is believed that the change in DC self-bias arises from the fact that the positively biased shield drains electrons from the plasma, thereby causing the plasma and hence the pedestal electrode to become more positive.

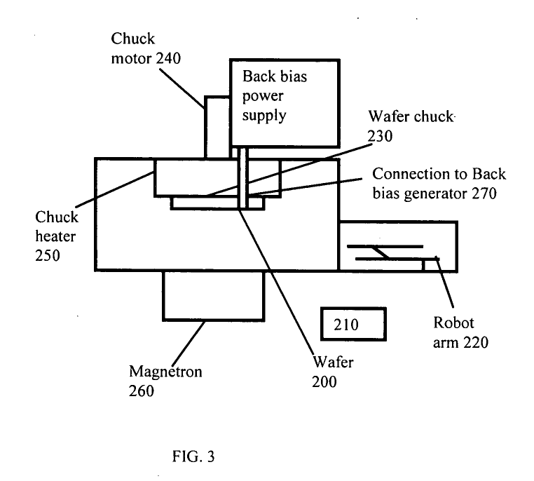

FIG. 3 shows another embodiment of an FTS system. In this embodiment, a wafer 200 is positioned in a chamber 210. The wafer 200 is moved into the chamber 210 using a robot arm 220. The robot arm 220 places the wafer 200 on a wafer chuck 230. The wafer chuck 230 is moved by a chuck motor 240. One or more chuck heaters 250 heats the wafer 200 during processing.

Additionally, the wafer 200 is positioned between the heater 250 and a magnetron 260. The magnetron 260 serves as highly efficient sources of microwave energy. In one embodiment, microwave magnetrons employ a constant magnetic field to produce a rotating electron space charge. The space charge interacts with a plurality of microwave resonant cavities to generate microwave radiation. One electrical node 270 is provided to a back-bias generator such as the generator 26 of FIG. 1.

In the system of FIG. 3, two target plates are respectively connected and disposed onto two target holders which are fixed to both inner ends of the chamber 210 so as to make the target plates face each other. A pair of permanent magnets are accommodated in the target holders so as to create a magnetic field therebetween substantially perpendicular to the surface of the target plates. The wafer 200 is disposed closely to the magnetic field (which will define a plasma region) so as to preferably face it. The electrons emitted from the both target plates by applying the voltage are confined between the target plates because of the magnetic field to promote the ionization of the inert gas so as to form a plasma region. The positive ions of the inert gas existing in the plasma region are accelerated toward the target plates. The bombardment of the target plates by the accelerated particles of the inert gas and ions thereof causes atoms of the material forming the plates to be emitted. The wafer 200 on which the thin film is to be disposed is placed around the plasma region, so that the bombardment of these high energy particles and ions against the thin film plane is avoided because of effective confinement of the plasma region by the magnetic field. The back-bias RF power supply causes an effective DC ‘back-bias’ between the wafer 200 and the chamber 210. This bias is negative, so it repels the low-velocity electrons.

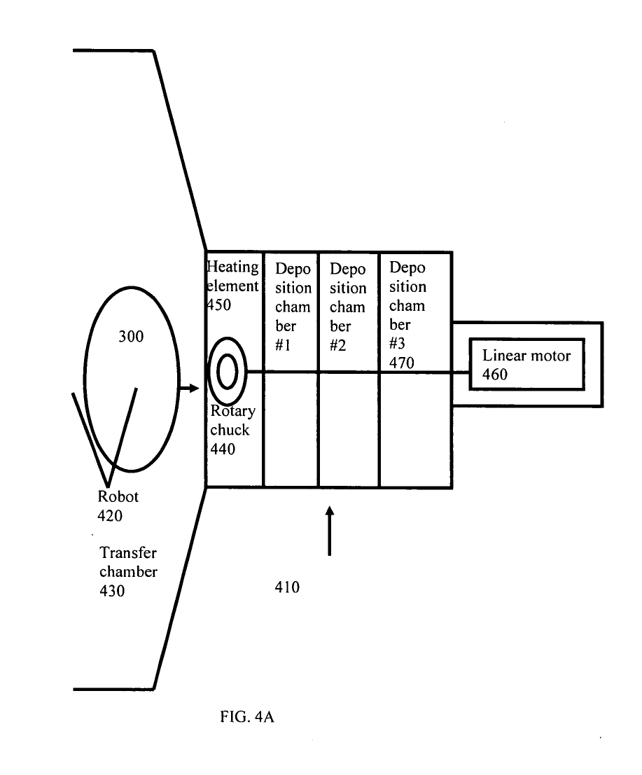

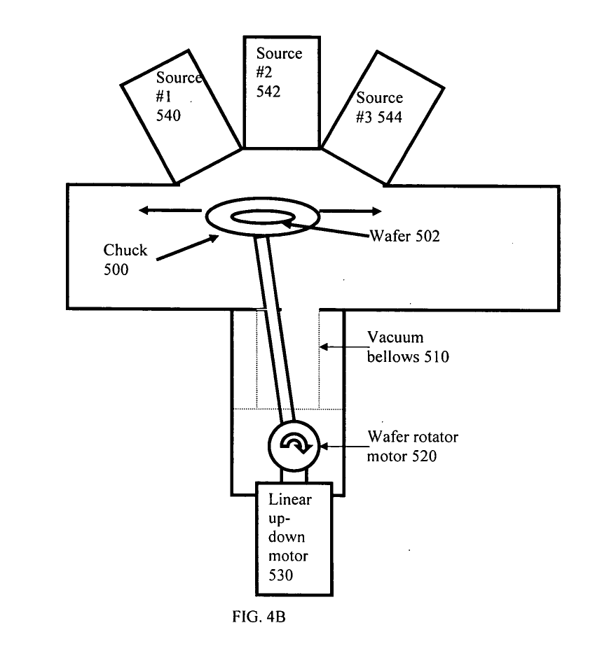

FIG. 4A shows one embodiment of a second apparatus for fabricating semiconductor. In the system of FIG. 4A, multiple 1-D deposition sources are stacked in the deposition chamber. The stacking of the sources reduces the amount of wafer travel, while significantly increasing deposition uniformity. A wafer 300 is inserted into a chamber 410 using a robot arm 420 moving through a transfer chamber 430. The wafer 300 is positioned onto a rotary chuck 440 with chuck heater(s) 450 positioned above the wafer. A linear motor 460 moves the chuck through a plurality of deposition chambers 470.

The system of FIG. 4A provides a plurality of one dimensional sputter deposition chambers. Each chamber can deposit a line of material. By moving the wafer 300 with the linear motor 460, 2-d coverage is obtained.

Turning now to FIG. 4B, a second embodiment of a fabrication apparatus is shown. In this embodiment, a chuck 500 is positioned inside a chamber. The chuck 500 supports a wafer 502. The chamber has vacuum bellows 510. The chuck 500 is driven by a wafer rotator 520 which rotates the wafer 502 and the chuck 500 in a pendulum-like manner. The chuck 500 is also powered by a linear motor 530 to provide up/down motion. A plurality of sources 540-544 perform deposition of materials on the wafer 502.

The system of FIG. 4B gets linear motion of the wafer 502 past the three sources for uniform deposition. This is done through a chuck supported from underneath rather than from the side. A jointed pendulum supports the wafer and keeps the wafer at a constant vertical distance from the target as the pendulum swings. The system swings the wafer using a pendulum. The system is more stable than a system with a lateral linear arm since the chuck 500 is heavy and supports the weight of the wafer, a heater, and RF back-bias circuitry and would require a very thick support arm otherwise the arm would wobble. Also, the linear arm would need to extend away from the source, resulting in large equipment. In this implementation, the arm sits below the chuck, resulting in a smaller piece of equipment and also the arm does not have to support much weight.

In one embodiment, a process for obtain 2D deposition coverage is as follows:

Receive desired 2D pattern from user

Move chuck into a selected deposition chamber;

Actuate linear motor and rotary chuck to in accordance with the 2D pattern

Move current wafer to next deposition chamber

Get next wafer into the current chamber and repeat process.

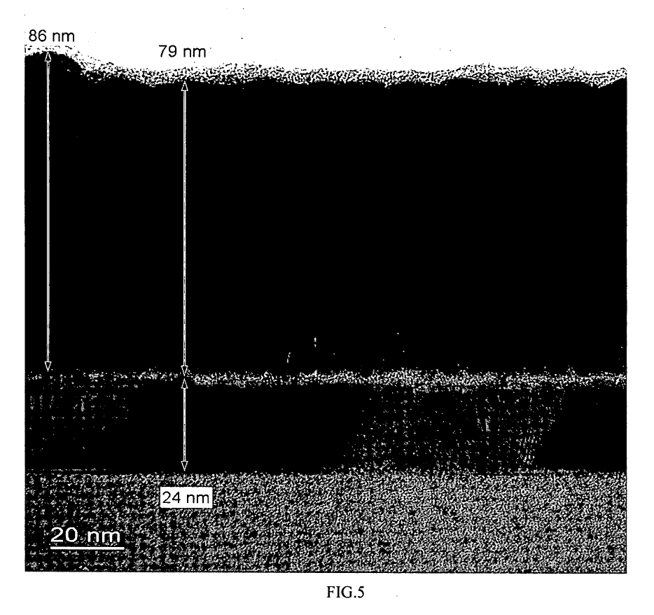

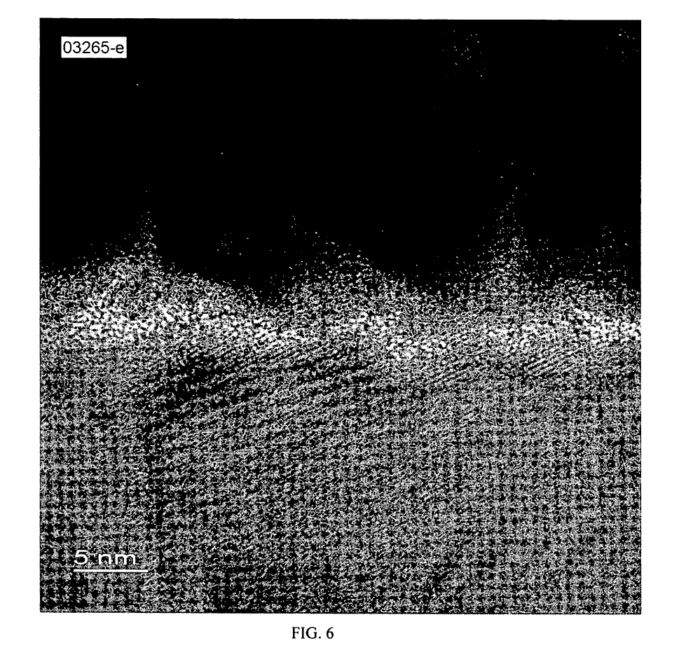

FIG. 5 shows an SEM image of an exemplary device fabricated with the system of FIG. 1, while FIG. 6 is an enlarged view of one portion of the SEM image of FIG. 5. The device of FIG. 5 was fabricated at a low temperature (below 400° C.). At the bottom of FIG. 5 is an oxide layer (20 nm thick). Above the oxide layer is a metal layer, in this case a titanium layer (24 nm thick). Above this layer is an interface layer, in this case a platinum (Pt) interface face layer (about 5 nm). Finally, a crystallite PCMO layer (79 nm thick) is formed at the top. Grains in this layer can be seen extending from the bottom toward the top with a slightly angled tilt. FIG. 6 shows a zoomed view showing the Ti metal layer, the Pt interface layer and the PCMO grain in more details.

Although one back-biased power supply is mentioned, a plurality of back-bias power supplies can be used. These power supplies can be controllable independently from each other. The electric energies supplied can be independently controlled. Therefore, the components of the thin film to be formed are easily controlled in every sputtering batch process. In addition, the composition of the thin film can be changed in the direction of the thickness of the film by using the Facing Targets Sputtering device.

One or more electronic devices can be formed on the wafer. The device can be non-volatile memory such as magneto-resistive random access memory (MRAM). Unlike conventional DRAM, which uses electrical cells (e.g., capacitors) to store data, MRAM uses magnetic cells. Because magnetic memory cells maintain their state even when power is removed, MRAM possesses a distinct advantage over electrical cells.

In one embodiment, the MRAMs formed using the above FTS has two small magnetic layers separated by a thin insulating layer typically make up each memory cell, forming a tiny magnetic “sandwich.” Each magnetic layer behaves like a tiny bar magnet, with a north pole and south pole, called a magnetic “moment.” The moments of the two magnetic layers can be aligned either parallel (north poles pointing in the same direction) or antiparallel (north poles pointing in opposite directions) to each other. These two states correspond to the binary states—the 1's and 0's—of the memory. The memory writing process aligns the magnetic moments, while the memory reading process detects the alignment. Data is read from a memory cell by determining the orientation of the magnetic moments in the two layers of magnetic material in the cell. Passing a small electric current directly through the memory cell accomplishes this: when the moments are parallel, the resistance of the memory cell is smaller than when the moments are not parallel. Even though there is an insulating layer between the magnetic layers, the insulating layer is so thin that electrons can “tunnel” through the insulating layer from one magnetic layer to the other.

To write to an MRAM cell, currents pass through wires close to (but not connected to) the magnetic cell. Because any current through a wire generates a magnetic field, this field can change the direction of the magnetic moment of the magnetic material in the magnetic cell. The arrangement of the wires and cells is called a cross-point architecture: the magnetic junctions are set up along the intersection points of a grid. Word lines run in parallel on one side of the magnetic cells. Bit lines runs on a side of the magnetic cells opposite the word lines. The bit lines are perpendicular to the set of word lines below. Like coordinates on a map, choosing one particular word line and one particular bit line uniquely specifies one of the memory cells. To write to a particular cell (bit), a current is passed through the word line and bit line that intersect at that particular cell. Only the cell at the crosspoint of the word line and the bit line sees the magnetic fields from both currents and changes state.

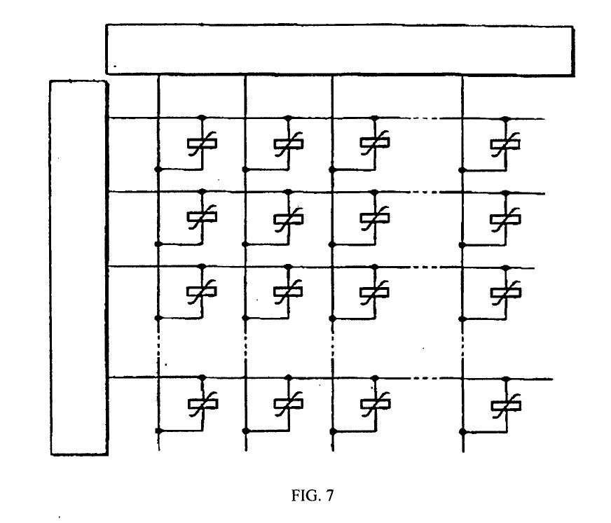

In one exemplary memory cell array shown in FIG. 7, word lines for selecting rows and bit lines for selecting columns are arranged to intersect at right angles. Memory cells are formed at intersections, and a peripheral driver circuit for selectively allowing information to be written into or read from the memory cells and an amplifier circuit which for reading the information are also formed. The peripheral circuit section includes a word line driver circuit and bit line driver circuit and a signal detecting circuit such as a sense amplifier, for example.

In another embodiment, the memory can be used in Programmable logic devices (PLDs) as well. PLDs can implement user-defined logic functions by interconnecting user-configurable logic cells through a variety of semiconductor switching elements. The switching elements may be programmable elements such as fuses or antifuses which can be programmed to respectively connect or disconnect logical circuits. As it is well known, a fuse is a device having two electrodes and a conductive element which electrically connects the two electrodes. When a fuse is programmed, by passage of sufficient current between its electrodes, the two electrodes are electrically disconnected. By contrast, an antifuse is a structure, having two electrodes, which are not electrically connected when unprogrammed. However, when programmed the first and second electrodes of the antifuse are permanently electrically connected. An antifuse can be programmed by applying sufficient voltage (“programming voltage”) between its first and second electrodes, thereby forming a bi-directional conductive link between the first and the second electrodes.

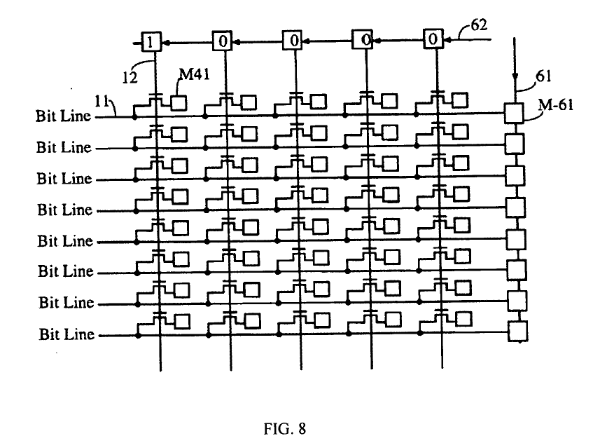

The configuration relating to the programming of the fuses or antifuses can be stored in the memory cells in one embodiment. FIG. 8 shows memory cells holding configuration data for an FPGA chip. The memory cells of FIG. 8 are made using the back-biased FTS technique as discussed above. A frame shift register 61 receives a bitstream and loads the array of memory cells. Address shift register 62 selects which column of memory cells is loaded from frame shift register 61. Selection of the column is made by shifting a token logical I through word line register 62. In the illustration of FIG. 8, the leftmost column holds the logical 1. Thus when frame shift register 61 is filled with a frame of bitstream data, and word line 12 is high the data bit in memory cell M-61 of shift register 61, is applied to bit line 11 and loaded into memory cell M41. Other memory cells are equivalently loaded.

In yet another embodiment, a separate memory array can be provided together with the FPGA configuration memory to allow a configured FPGA device to access the memory array as a buffer, for example.

It is to be understood that various terms employed in the description herein are interchangeable. Accordingly, the above description of the invention is illustrative and not limiting. Further modifications will be apparent to one of ordinary skill in the art in light of this disclosure.

The invention has been described in terms of specific examples which are illustrative only and are not to be construed as limiting. The invention may be implemented in digital electronic circuitry or in computer hardware, firmware, software, or in combinations of them.

Apparatus of the invention for controlling the fabrication equipment may be implemented in a computer program product tangibly embodied in a machine-readable storage device for execution by a computer processor; and method steps of the invention may be performed by a computer processor executing a program to perform functions of the invention by operating on input data and generating output. Suitable processors include, by way of example, both general and special purpose microprocessors. Storage devices suitable for tangibly embodying computer program instructions include all forms of non-volatile memory including, but not limited to: semiconductor memory devices such as EPROM, EEPROM, and flash devices; magnetic disks (fixed, floppy, and removable); other magnetic media such as tape; optical media such as CD-ROM disks; and magneto-optic devices. Any of the foregoing may be supplemented by, or incorporated in, specially-designed application-specific integrated circuits (ASICs) or suitably programmed field programmable gate arrays (FPGAs).

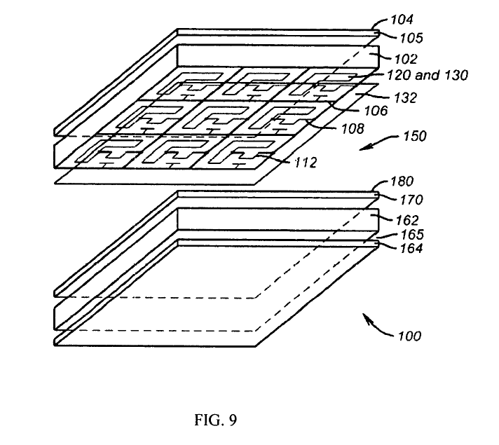

Turning now to FIG. 9, an exemplary LCD is shown. The exemplary LCD 100 that is formed by placing first and second glass substrates or plates 102 and 162 close to one another with a small gap formed between the plates 102 and 162. The first and second glass plates 102 and 162 are independently processed using the back-biased technique discussed above, and the processing of each plate includes the deposition of various layers, device patterning and other techniques. After the plates 102 and 162 are processed, they are mated together and a liquid crystal material 150 is injected into the gap between the plates.

The first glass plate 102 has a polarizing film 104 on its outer surface. A spacer layer 105 can be provided between the polarizing film 104 and the glass plate 102. On the inner surface of the plate 102, a transparent electrical conductor 106 is deposited. The transparent conductor 106 is patterned into a series of mutually perpendicular lines (row and column lines) that designate a plurality of cells or pixels 108. One or more switching devices 112 are connected to the individual pixel electrodes 120. The pixel electrodes 120 can be made of, for example, ITO (indium tin oxide) that is superposed on one end of a drain electrode of a suitable switching device on a superposed semiconductor layer. The pixel electrode 120 is deposited or formed in a predetermined region in the cell and separated from an adjacent pixel electrode 120 by such an extent of gap that they can be electrically insulated from each other. The reflection from the ITO layer can be enhanced or degraded by including collection layers with a thickness a specific fraction of the incoming light wavelength.

The switching devices 112 can be thin film transistors (TFT). In each TFT, a drain electrode is connected to the corresponding pixel electrode 120; a source electrode is connected to a signal line; and a gate electrode is connected to a gate line. The TFT drives the pixel electrode 120 to cause a pixel to be turned on and off to display a portion of the image on the screen by applying a voltage to the pixel electrode 120. The voltage controls the orientation state of the liquid crystal 150 so that light entering from the other substrate is allowed to pass through or blocked. The switching devices 112 apply a voltage for displaying to the picture element electrode. This voltage controls the orientation state of the liquid crystal so that light entering from the other substrate is allowed to pass through or be blocked. Light which has passed through the liquid crystal layer is reflected by the picture element electrode which is a reflector and then emitted from the display device, resulting in a bright display. When the entering light is blocked a dark display is obtained.

Turning now to the second glass substrate or plate 162, the second glass plate 162 also has a polarizing film 164 on its outer surface. A spacer layer 165 can be provided between the polarizing film 164 and the glass plate 162. The facing electrodes 170 can be made of, for example, ITO (indium tin oxide) that is superposed on one end of a drain electrode of a suitable switching device on a superposed semiconductor layer. The facing electrodes 170 apply a vertical electric field to the liquid crystal layer 150. In addition, the second glass substrate or plate 162 includes a color filter layer with segments divided into the primary colors, that is, red, green and blue. The segment are each matched with the pixel electrodes 120. The pixel electrodes 120 and the facing electrodes 170 generate a vertical electric field such that that the molecular alignment of the liquid crystal layer 150 is changed.

The gap between the plates 102 and 162 is filled with the liquid crystal layer 150 such as a liquid crystal polymer material, typically a cyanobiphenyl with the ability to rotate the direction of polarized light. Polarization direction follows the physical rotation of the liquid crystal molecules, i.e., the direction of the long axis of the molecules. The liquid crystal material is used which forms loosely organized chains that rotate from one side of the gap to the other side. As such chains rotate or “twist,” so do the axes of the individual liquid crystal molecules. Light, which is polarized as it passes through the polarizing film 164, has its polarization direction rotated following the physical rotation of the liquid crystal polymer molecules as the light passes through the cell. The polarizing film 104 on the top side of the display passes light that has had it polarization direction rotated in the manner described. Viewed from the top, such a cell is clear, or transmitting. The alignment of the liquid crystal molecules, and, hence, the polarization direction of light passing through the liquid crystal, can be changed by applying an external electric field. Applying a voltage across the cell gap by addressing the appropriate line on each side of the cell causes the chains of liquid crystal molecules to align themselves with the applied electric field, “untwisting” as they align. Since the polarization direction of light passing through such “untwisted” liquid crystal polymer is not rotated, such light is blocked from exiting the cell by the polarizing field, which passes only rotated light. Such a cell appears dark from the exit side. When the voltage is turned off, the liquid crystal returns to its original state, and the pixel is clear again.

A backlight can be disposed on a planar surface of the liquid crystal display 100 so as to construct the liquid crystal display device. In one embodiment, the backlight includes a light guide plate which is made of a transparent acrylic plate provided with a surface treatment for giving the light directivity to the plate, a linear lamp such as a cold cathode fluroescent tube arranged along one side of the light guide plate and a reflection sheet.

Although FIG. 1 shows a liquid crystal panel for a monochromatic display, the panel can be converted to the one for a color display by merely providing three color filters to the inner surface of the upper substrate or the lower substrate.

While the preferred forms of the invention have been shown in the drawings and described herein, the invention should not be construed as limited to the specific forms shown and described since variations of the preferred forms will be apparent to those skilled in the art. Thus the scope of the invention is defined by the following claims and their equivalents.

What is claimed is:

1. A facing targets sputtering device for semiconductor fabrication, comprising:
an air-tight chamber in which an inert gas is admittable and exhaustible;
a pair of target plates placed at opposite ends of said air-tight chamber respectively so as to face each other and form a plasma region therebetween;
a pair of magnets respectively disposed adjacent to said target plates such that magnet poles of different polarities face each other across said plasma region thereby to establish a magnetic field of said plasma region between said target plates;
a substrate holder disposed adjacent to said plasma region, said substrate holder adapted to hold a substrate on which an alloyed thin film is to be deposited;
a back-bias power supply coupled to the substrate holder; wherein the substrate includes an array of liquid crystal display (LCD) devices formed thereon.

2. A facing targets sputtering device according to claim 1, wherein the back-bias power supply is a DC or an AC electric power source.

3. A facing targets sputtering device according to claim 1, further comprising a first target power supply coupled to one of the target plates.

4. A facing targets sputtering device according to claim 3, wherein the first target power supply is a DC or an AC electric power source.

5. A facing targets sputtering device according to claim 1, further comprising a second target power supply coupled to the remaining target plate.

6. A facing targets sputtering device according to claim 1, wherein the first and second target power supplies comprises DC and AC electric power sources.

7. A facing targets sputtering device according to claim 1, further comprising a robot arm to move the wafer.

8. A facing targets sputtering device according to claim 1, further comprising a magnetron coupled to the chamber.

9. A facing targets sputtering device according to claim 1, further comprising a chuck heater mounted above the wafer.

10. The apparatus of claim 1, wherein the FTS further comprises first and second targets mounted in parallel.

11. The apparatus of claim 10, further comprising magnets positioned between the first and second targets.

12. The apparatus of claim 10, further comprising a power supply coupled to the magnets and the targets.

13. The apparatus of claim 10, wherein the substrates are positioned perpendicularly to the planes of the targets.

14. The apparatus of claim 13, further comprising a substrate holder to secure the substrate.

15. The apparatus of claim 1, wherein the semiconductor layer is a CMOS layer.

16. A method for sputtering a thin film onto a substrate, comprising:
providing at least one target and a substrate having a film-forming surface portion and a back portion;
creating a magnetic field so that the film-forming surface portion is placed in the magnetic field with the magnetic field induced normal to the substrate surface portion
back-biasing the back portion of the substrate; and
sputtering material onto the film-forming surface portion, wherein the thin forming surface portion comprises a liquid crystal display device.

17. A method as in claim 16 including providing a pair of said targets opposed to each other where the substrate is disposed between the targets.

18. A method as in claim 16, further comprising swinging the wafer using a pendulum.

19. A method as in claim 16, further comprising supporting a chuck from underneath rather than side-way.

20. A method as in claim 16, further comprising providing a plurality of sources to deposit materials onto the substrate.
